(19) United States
(12) Patent Application Publication
(10) Pub. No.: US 2009/0053646 A1
(43) Pub. Date: Feb. 26, 2009

(54) MATERIAL FOR PROTECTIVE FILM FORMATION AND METHOD OF FORMING RESIST PATTERN THEREWITH

(76) Inventors: Keita Ishiduka, Kanagawa (JP); Kotaro Endo, Kanagawa (JP)

Correspondence Address: PROCOPIO, CORY, HARGREAVES & SAVITCH LLP, 530 B STREET, SUITE 2100, SAN DIEGO, CA, 92101, US

(21) Appl. No.: 11/912,423

(22) PCT Filed: Apr. 13, 2006
(86) PCT No.: PCT/JP2006/307864

§ 371 Date: Oct. 24, 2007

(30) Foreign Application Priority Data
Apr. 25, 2005 (JP) 2005-126703

(51) Int. Cl. G03F 7/11; G03F 7/20

(52) U.S. Cl. 430/271.1; 430/325

(57) ABSTRACT

A material for protective film formation that is used to form an upper-layer protective film for a resist film and that contains at least a polymer component soluble in water or alkali and an alcohol containing a fluorine atom; and a method of forming a resist pattern with the use of the same. Consequently, not only can the degeneration of resist film during liquid immersion exposure by various liquids for liquid immersion exposure, for example, water and the degeneration of liquid immersion exposure liquids per se be simultaneously prevented in the liquid immersion exposure process, but also without inviting an increase of the number of processing steps, the resistance to post exposure delay of the resist film can be enhanced.

### TECHNICAL FIELD

The present invention relates to a material for forming a protective film that is suitable for forming a protective film on a resist film, and a method for forming a resist pattern using the same. Particularly, the present invention relates to a material for forming a protective film which can be suitably used in a liquid lithography process, which is an exposure process in which a resist pattern is obtained by exposing a resist film, while being intervened, in the pathway through which the exposure light for lithography reaches the resist film, by a liquid having a refractive index higher than that of an air and lower than that of the resist film (hereinafter referred as to “liquid for liquid immersion lithography”), and a method for forming the resist pattern using the same.

### BACKGROUND ART

A lithography process is frequently used for producing a microstructure in various electronic devices such as a semiconductor device, a liquid crystal device, or the like. However, together with the microfabrication of a device structure, a finer resist pattern is required in the lithography process.

In the advanced field, for example, a lithography process now allows the formation of a fine resist pattern having a line width of about 90 nm. However, finer pattern formation will be required in future.

For attaining the formation of such a fine pattern having a line width of less than 90 nm, a first point is to develop an aligner and a resist corresponding thereto. Common factors to consider for developing the aligner include shortening of wavelengths of light sources such as F₂ excimer laser, EUV (extreme UV light), electron beam, X-ray, soft X-ray and the like, and increases in numerical aperture (NA) of lens.

However, for shortening wavelengths of light sources, a new expensive exposure apparatus is required. In addition, even the resolution increases, a disadvantage of lowering a focal depth width occurs at high NA due to a trade-off relationship between the resolution and the focal depth width.

Recently, as a lithography technology for allowing such problems to be solved, a method known as a liquid immersion lithography process has been reported (e.g., Non-Patent Documents 1, 2, and 3). This method includes allowing a liquid for liquid immersion lithography to intervene between a lens and a resist film on a substrate at the time of exposure. In this method, the space of the path of exposure light, which is conventionally filled with an inert gas such as air or nitrogen, is replaced with a liquid having a higher refractive index (n), for example pure water, to attain high resolution without a decrease in focal depth width, similarly to the use of a light source of shorter wavelength or a high NA lens, even if a light source having the same exposure wavelength is employed.

Such liquid immersion lithography process has been given considerable attention because its use allows a lens implemented in the existing device to realize the formation of a resist pattern superior in higher resolution property as well as excellent in focal depth at low costs.

However, in such a liquid immersion lithography process, a liquid for liquid immersion lithography such as pure water or inert fluorinated (fluorine-based) liquid is intervened on the top layer of the resist film, so that it is concerned naturally enough that the quality of the resist film during liquid immersion lithography is deteriorated by the liquid for liquid immersion lithography, and a refractive index associated with deterioration of the liquid itself for liquid immersion lithography by an eluted component from the resist film is varied.

In such a liquid immersion lithography process, materials used in a conventional lithography process may be used as is; however, there is a difference in an exposure condition in which the liquid for liquid immersion lithography is intervened between a lens and a resist film, and therefore, it is suggested that materials different from those of the conventional lithography process be used.

Under such circumstances, materials for forming a protective film using a fluorine-containing resin have been proposed as a means for preventing from both deterioration of the quality of the resist film during liquid immersion lithography by the liquid for liquid immersion lithography and variation of a refractive index associated with deterioration of the liquid itself for liquid immersion lithography (see, for example, Patent Document 1). However, when such a material for forming a protective film is used, though the aforementioned purpose is attained, problems on the investment efficiency are caused such as those due to the necessity for a special cleaning solution and an applying device for it as well as an increase in the number of processes for removing the protective film.

Furthermore, recently, a process in which a water-insoluble and alkali-soluble polymer is used as a protective film on the resist top layer has drawn considerable attention, so that there has been a strong demand for characteristics enabling to control deterioration of the quality of the resist film during liquid immersion lithography by the liquid for liquid immersion lithography and variation of a refractive index associated with deterioration of the liquid itself for liquid immersion lithography for materials for forming this kind of protective film, wherever possible.

Non-Patent Document 1: Journal of Vacuum Science & Technology B (J. Vac. Sci. Technol. B) (Issued in U.S.A.), Vol. 17, No. 6, ages 3306-3309, 1999.

Non-Patent Document 2: Journal of Vacuum Science & Technology B (J. Vac. Sci. Technol. B) (Issued in U.S.A.), Vol. 19, No. 6, pages 2353-2356, 2001.

Non-Patent Document 3: Proceedings of SPIE (Issued in U.S.A.), Vol. 4691, pages 459-465, 2002.

Patent Document 1: International Patent Application Publication No. WO 2004/074937

### DISCLOSURE OF THE INVENTION

### Problems to be Solved by the Invention

In consideration of the abovementioned problems, an object of the present invention is to provide an alkali-soluble material for forming a protective film enabling to control deterioration of the quality of the resist film during liquid immersion lithography by the liquid for liquid immersion lithography and variation of a refractive index associated with deterioration of the liquid itself for liquid immersion lithography, wherever possible.

### Means for Solving the Problems

To achieve the abovementioned objects, the material for forming a protective film according to the present invention is a material for forming a protective film of a resist film top layer including a water-soluble or alkali-soluble polymer component and a fluorine atom containing alcohol.

Furthermore, a method for forming a resist pattern of the present invention is a method for forming a resist pattern using a liquid immersion lithography process, the method including: forming a resist film on a substrate; forming a protective film on the resist film using the material for forming a protective film; placing a liquid for liquid immersion lithography on the substrate having the resist film and the protective film layered thereon; irradiating the resist film with a predetermined exposure light through the liquid for liquid immersion lithography and the protective film; performing a heat treatment if necessary; and washing the protective film and the resist film by using an alkaline developer solution to remove the protective film, and simultaneously developing the resist film to obtain a resist pattern.

### EFFECTS OF THE INVENTION

The material for forming a protective film of the present invention can be directly used to form on a resist film and does not inhibit pattern exposure. In other words, the material for forming a protective film for the resist according to the present invention can sufficiently protect resist films having various compositions, thereby enabling to obtain a resist pattern having superior characteristics, even in a liquid immersion lithography process using a liquid for liquid immersion lithography, which is easily handled and has excellent refractive index characteristic.

Furthermore, the material for forming a protective film according to the present invention does not necessitate removal of the formed protective film from the resist film prior to the developer treatment even when the light exposure is completed reaching the step of the developer treatment. That is, by using the protective film obtained using the material for forming a protective film according to the present invention, it is unnecessary to set up the step of removing the protective film prior to the developer treatment after exposure such that the developer treatment for the resist film with an alkaline developer solution can be performed as the protective film remains, whereby the protective film removal and the resist film development can be simultaneously accomplished. Therefore, the method for forming the pattern using the material for forming a protective film according to the present invention can efficiently form the resist film with an excellent pattern property while keeping the environmental pollution risk extremely low and reducing the number of processes.

A feature of the material for forming a protective film for the resist of the present invention is that a fluorine atom containing alcohol is included. By employing such a fluorine atom containing alcohol, it is possible to control solubility in a resist film, improve film coating property, control the amount of a residual solvent, and further polarize by controlling orientation of the resin.

Furthermore, in the present invention, an acidic component is preferably added so as to further improve an environmental amine resistance of a protective film. As the acidic component, a specific fluorocarbon compound described hereinafter is preferably used. The effect of improving coatability when coating the material for forming a protective film on the resist film is also exhibited by the addition of the specific fluorocarbon compound. As described above, when a protective film containing this specific fluorocarbon compound added therein is used, it is possible to further improve the environmental amine resistance after pattern exposure of a resist film.

Accordingly, by adding a specific fluorocarbon compound described hereinafter as the acidic component to the material for forming a protective film, the superior characteristics of preventing a resist film from an amine action after exposure can be provided.

As described above, the characteristics required for the protective film of the present invention are: being necessarily water-soluble or alkali-soluble, and transparent to exposure light, not being mixed with a resist film, exhibiting good adhesion to a resist film and good miscibility with a developing solution, and being dense and capable of preventing permeation of environmental amines. The material for forming a protective film, which can form a resist protective film having these characteristics, is a material containing a water-soluble or alkali-soluble polymer and a fluorine containing alcohol.

### PREFERRED MODE FOR CARRYING OUT THE INVENTION

### (I) Polymer Component

The “water-soluble or alkali-soluble polymer” suited for use as a base polymer of the protective film of the present invention includes the following fluoropolymer. That is, the fluoropolymer preferably has the following constitutional unit included in a polymer comprising a nonaqueous and alkaline-soluble constitutional unit (X), which has both (X-1) a fluorine atom or a fluorinated alkyl group, and (X-2) an alcoholic hydroxyl group or an oxyalkyl group.

In the constitutional unit (X), a fluorine atom or a fluorinated alkyl group (X-1), and an alcoholic hydroxyl group or an alkyloxy group (X-2) are each bonded on an aliphatic ring structure, in which the cyclic structure constitutes a main chain. Examples of the fluorine atom or fluorinated alkyl group (X-1) include a fluorine atom or lower alkyl groups having a portion or all of hydrogen atoms thereof being substituted with a fluorine atom. Specific examples thereof include a trifluoromethyl group, a pentafluoroethyl group, a heptafluoropropyl group, a nonafluorobutyl group and the like, and a fluorine atom and a trifluoromethyl group are preferable from an industrial point of view. In the alcoholic hydroxyl group or alkyloxy group (X-2), the alcoholic hydroxyl group may be merely a hydroxyl group, and the alkyloxy group is a linear, branched or cyclic alkyloxyalkyl group having 1 to 15 carbon atoms, or an alkyloxy group.

The base polymer having such a unit is formed by cyclic polymerization of a diene compound having a hydroxyl group and a fluorine atom. The diene compound is preferably heptadiene capable of easily forming a polymer having a 5- or 6-membered ring, which is excellent in transparency and dry etching resistance. Furthermore, a polymer formed by cyclic polymerization of 1,1,2,3,3-pentafluoro-4-trifluoromethyl-4-hydroxy-1,6-heptadiene (CF₂═CFCF₂C(CF₃) (OH)CH₂CH═CH₂) is most preferable from an industrial point of view.

The general formula (3), which represents the polymer, is shown below.

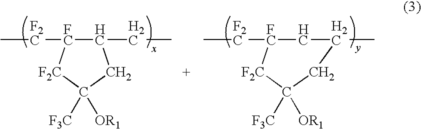

In the general formula (3), R₁ represents a hydrogen atom, a linear, branched or cyclic C1-C15 alkyloxy group, or an alkyloxyalkyl group; and x and y each represents the content of 0 to 100% by mole.

Such a polymer can be synthesized by a known method. A polystyrene equivalent mass average molecular weight of a resin of the polymer component, determined by GPC, is not specifically limited, and is preferably from 5,000 to 80,000, and more preferably from 8,000 to 50,000.

Examples of the “water-soluble or alkali-soluble polymer” suited for use as a base polymer of the material for forming a protective film of the present invention can further include the following acrylic polymer.

The acrylic polymer which can be used in the invention is a polymer having at least a constitutional unit represented by the following general formula (1) as its constitutional unit:

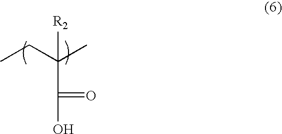

wherein R₂ represents a hydrogen atom, a methyl group, or a hydroxyalkyl group having 1 to 5 carbon atoms.

The acrylic polymer used in the present invention may further have a constitutional unit represented by the following general formula (7) as well as a constitutional unit represented by the above general formula (6). By having these constitutional units, contact angle with resist protective film and a liquid for liquid immersion lithography can be improved.

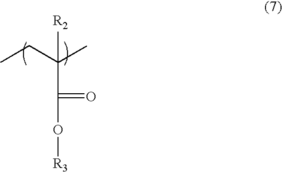

wherein, R₂ represents a hydrogen atom, a methyl group, or a hydroxyalkyl group having 1 to 5 carbon atoms; and R₃ represents a hydrocarbon group having at least one or more alicyclic structure.

The constitutional unit represented by the above general formula (7) is preferably composed of two kinds of constitutional units of: the constitutional unit represented by the following general formula (8); and the constitutional unit represented by the following general formula (9):

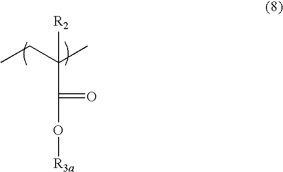

wherein R₂ represents a hydrogen atom, a methyl group, or a hydroxyalkyl group having 1 to 5 carbon atoms; and R₃ₐ represents a polycyclic hydrocarbon group; and

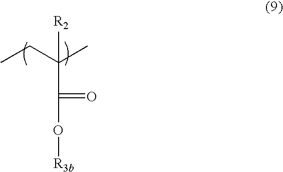

wherein R₂ represents a hydrogen atom, a methyl group, or a hydroxyalkyl group having 1 to 5 carbon atoms; and R_{3b} represents a monocyclic hydrocarbon group.

R₃ₐ is preferably at least one hydrocarbon group selected from a cyclopenthanyl group, an adamantyl group, a norbornyl group, an isobornyl group, a tricyclodecyl group, and a tetracyclododecyl group, which may be substituted or unsubstituted with a hydroxyl group.

R_{3b} preferably is at least one hydrocarbon group selected from a tricyclodecyl group, a cyclopentyl group, a cyclohexyl group, and a cycloheptyl group.

The acrylic polymer used in the present invention may further have a constitutional unit represented by the following general formula (10) as well as a constitutional unit represented by the above general formula (7). By having these constitutional units, film coating property can be improved.

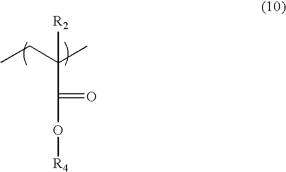

wherein, R₂ represents a hydrogen atom, a methyl group, or a hydroxyalkyl group having 1 to 5 carbon atoms; and R₄ represents a substituted or unsubstituted, branched or linear alkyl group having 1 to 10 carbon atoms.

R₄ represents preferably at least one group selected from a n-butyl group, an isobutyl group, a n-pentyl group, a n-hexyl group, and a 2-ethylhexyl group.

More specifically, such an acryl polymer is a polymer having a constitutional unit represented by the following general formula (11):

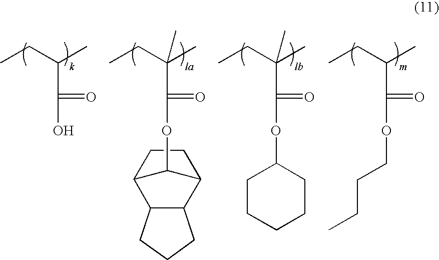

wherein k, la, lb, and m each represent % by mole of the constitutional unit included in the polymer, which are each 5 to 50% by mole.

In the constitutional unit represented by the above general formula (11), an acryl constitutional unit at the left end, which accounts for k % by mole, is a component which mainly contributes to alkaline-solubility of the present acrylic polymer. Also, the constitutional unit having two kinds of central alicyclic structures, which account for la % by mole and lb % by mole, respectively, is a component which mainly contributes to a contact angle of the present acrylic polymer. Also, a constitutional unit at the right end, which accounts for m % by mole, is a component which mainly contributes to film coating properties of the present acrylic polymer. Therefore, in the present invention, it is possible to obtain a material for forming a protective film, which is best suited for use conditions, by appropriately controlling k % by mole of the component capable of contributing to alkaline solubility, l (la+lb) % by mole of the component capable of contributing to a contact angle and m % by mole of the component capable of contributing to coatability. Although each % by mole may slightly vary depending on the use conditions, k is preferably from 5 to 90% by mole, l (=la+lb) is preferably from 5 to 90% by mole, and m is preferably from 5 to 90% by mole.

Such a polymer can be synthesized by a known method. Also, a polystyrene equivalent weight average molecular weight determined by GPC of the resin of the polymer component is not specifically limited, and is from 3,000 to 50,000.

The polymer is soluble in a fluorine atom containing alcohol, can form a film by a spin coater, causes neither swelling nor thickness loss to pure water within a time sufficient for liquid immersion lithography, and is also soluble in an alkaline developing solution. That is, the polymer is highly suited for use as a resist protective film material for liquid immersion lithography. Moreover, this polymer has a high refractive index of 1.6655 (absorption coefficient=0.0016) upon transmission of a light having a wavelength of 193 nm.

Amount of the polymer is preferably 0.1 to 30% by mass, and more preferably 1 to 20% by mass in the material for forming a protective film.

Thus, the film formed by using the acryl polymer has a suitable contact angle. It is considered necessary for a protective film for liquid immersion lithography to have an additional characteristic in which a contact angle thereof to the liquid for liquid immersion lithography is a predetermined value, because if the contact angle is too large when a liquid for liquid immersion lithography is placed on a protective film, the liquid for liquid immersion lithography is repelled, and therefore the physical stability of the liquid for liquid immersion lithography is impaired. In contrast, when the contact angle is too small, the amount of the liquid for liquid immersion lithography adhered on the protective film increases, and not only does it require a long time to wash after completion of liquid immersion lithography process, but also unnecessary discharge of the liquid for liquid immersion lithography out of the system (hereinafter referred to as “medium leakage”) occurs, resulting in diseconomy.

In addition, the polymer is preferably a water-insoluble and alkali-soluble polymer when water is used as the liquid for liquid immersion lithography in a liquid immersion lithography process.

### (II) Fluorine Atom Containing Alcohol

The material for forming a resist protective film of the present invention contains a fluorine atom containing alcohol as a solvent in which the water-soluble or alkali-soluble polymer is dissolved. The fluorine atom containing alcohol used in the present invention has no compatibility with a resist film and can dissolve the polymer.

The fluorine atom containing alcohol used in the present invention preferably has the number of the fluorine atoms larger than that of the hydrogen atoms included in the molecule thereof.

In addition, the number of carbon atoms in the fluorine atom containing alcohol is preferable 4 to 12.

The fluorine containing alcohol satisfying two conditions as described above is preferably an alcohol represented by the following chemical formula (1):

C₄F₉CH₂CH₂OH (1),

and/or an alcohol represented by the following chemical formula (2):

C₃F₇CH₂OH (2),

for example.

Any solvent can be used as long as it has no compatibility with a resist film and can dissolve the polymer in the range not to inhibit the action of the fluorine containing alcohol. Examples of such a solvent include merely alcoholic solvents, paraffinic solvents and fluorine-based solvents. As the alcoholic solvent, a common alcoholic solvent such as isopropyl alcohol, 1-hexanol, 2-methyl-1-propanol or 4-methyl-2-pentanol can be used, and 2-methyl-1-propanol and 4-methyl-2-pentanol are particularly preferable. It has been confirmed that n-heptane can be used as a paraffinic solvent and perfluoro-2-butyltetrahydrofuran can be used as a fluorine-based solvent.

### (III) Cross-linking Agent

The material for forming a resist protective film of the present invention may include a crosslinking agent. The crosslinking agent used in the present invention is not particularly limited as long as it is soluble in the solvent. Among these, a nitrogen-containing compound that has an amino group and an imino group, which is substituted with a hydroxyalkyl group and/or an alkoxyalkyl group, can be preferably used.

As the nitrogen-containing compound, at least one selected from a melamine derivative, a guanamine derivative, a glycoluril derivative, a succinylamide derivative, and a urea derivative is preferably used.

Specifically, these nitrogen-containing compounds can be obtained, for example, by methylolating the abovementioned melamine-based compound, urea-based compound, guanamine-based compound, acetoguanamine-based compound, benzoguanamine-based compound, glycoluril-based compound, succinylamide-based compound or ethyleneurea-based compound through a reaction with formalin in boiling water, and optionally further alkoxylating the reaction product through a reaction with a lower alcohol, for example, methanol, ethanol, n-propanol, isopropanol, n-butanol or isobutanol.

As the crosslinking agent, tetrabutoxymethylated glycoluril is more preferably used.

Furthermore, as the crosslinking agent, a condensation reaction product of a hydrocarbon compound substituted with at least one hydroxyl group and/or alkyloxy group; and a monohydroxymonocarboxylic acid compound can also be preferably used.

The monohydroxymonocarboxylic acid is preferably monohydroxymonocarboxylic acid in which a hydroxyl group and a carboxyl group are respectively bonded to the same carbon atom, or adjacent two carbon atoms.

The material for forming a resist protective film of the present invention can further include an acidic component. The reason is, when a resist film is allowed to stand in an atmosphere containing a trace amount of amine before development after being subjecting to liquid immersion lithography, in addition to having characteristics which enable the physical prevention from influence of amine by densification of the protective film via a crosslinking agent, an acidic component in the protective film can chemically inhibit an adverse influence of amine. In addition, when the crosslinking agent and the acidic component are simultaneously used as a component of the material for forming a protective film, the size of a resist pattern obtained by the development after being allowed to stand does not vary drastically.

As the acidic component, a fluorocarbon compound is preferred. The fluorocarbon compound which exerts the above action, shown below, is not an object of Significant New Use Rule (SNUR) and is a usable chemical substance.

Examples of such a fluorocarbon compound include fluorocarbon compound represented by the following general formula (12):

(CₙF₂ₙ₊₁SO₂)₂NH (12),

wherein n is an integer of 1 to 5;

fluorocarbon compounds represented by the following general formula (13):

C_{z}F_{2z+1}COOH (13),

wherein m is an integer of 10 to 15;

fluorocarbon compounds represented by the following general formula (14); and fluorocarbon compounds represented by the following general formula (15):

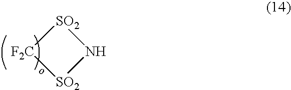

wherein o represents an integer of 2 to 3;

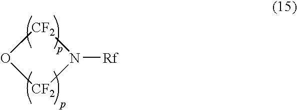

wherein p represents an integer of 2 to 3; and Rf represents an alkyl group in which a portion or all of hydrogen atoms thereof are substituted with a fluorine atom, and may be substituted with a hydroxyl group, an alkoxy group, a carboxyl group or an amino group.

As the fluorocarbon compound represented by the general formula (12), specifically, the fluorocarbon compound represented by following chemical formula (16):

(C₄F₉SO₂)₂NH (16)

or the following chemical formula (17):

(C₃F₇SO₂)₂NH (17)

is preferable.

Moreover, as the fluorocarbon compound represented by the general formula (13), specifically, the fluorocarbon compound represented by the following chemical formula (18):

C₁₀F₂₁COOH (18)

is preferable.

Specifically, the fluorocarbon compound represented by the general formula (14) is preferably a fluorocarbon compound represented by the following chemical formula (19).

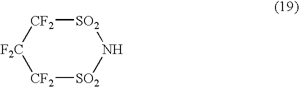

Specifically, the fluorocarbon compound represented by the general formula (15) is preferably a fluorocarbon compound represented by the following chemical formula (20).

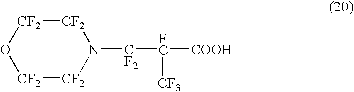

The amount of the crosslinking agent is preferably 0 to 10% by mass based on the amount of the fluorine containing alcohol.

### (IV) Materials for Resist Film

The protective film obtained from the material for forming a resist protective film of the present invention is nonaqueous and also exhibits high resistance to the other immersion liquids, and therefore can be applied to resist films with any composition, including resist films having low resistance to liquids for liquid immersion lithography. Therefore, as the material for a resist film, any known resist materials can be used and common positive resist materials and negative resist materials can be used.

### (V) Method for Forming Resist Pattern

A resist pattern forming method for liquid immersion lithography using the material for forming the resist protective film of the present invention will now be described.

First, a common resist composition is coated onto a substrate such as silicone wafer using a spinner or the like, and then prebaked (PAB treatment). An organic or inorganic antireflective film can be provided between the substrate and the coating layer of the resist composition, to form a two-layered laminate.

The above processes can be conducted by a known method. It is preferable that the operation conditions etc. are appropriately set according to the composition and characteristics of the resist composition used.

Next, the protective film is formed by uniformly coating, on the surface of thus formed resist film, the material for forming a resist protective film of the present invention, which is obtained by dissolving an alkali-soluble resin represented by the above chemical formula (5) in C₄F₉CH₂CH₂OH.

The substrate on which a resist film covered with the protective film is formed is immersed in a liquid for liquid immersion lithography.

The resist film in an immersed state is selectively exposed via a desired mask pattern. Accordingly, the exposure light penetrates through the liquid for liquid immersion lithography and the protective film, reaching the resist film in this process.

At this time, the resist film is completely blocked from the liquid for liquid immersion lithography such as pure water, by the protective film, and thus deterioration such as swelling is not caused by permeation of the liquid for liquid immersion lithography. In addition, deterioration of the optical characteristics such as the refractive index of the liquid for liquid immersion lithography itself can be avoided, which may result from dissociation of a component in the liquid for liquid immersion lithography (pure water, deionized water, or a fluorine-based solvent).

The wavelength of the light used in the exposure is not specifically limited, and the exposure can be conducted by using radiation such as an ArF excimer laser, KrF excimer laser, F₂ excimer laser, EUV (extreme ultraviolet ray), VUV (vacuum ultraviolet ray), electron beam, X-ray and soft X-ray, etc.

As described above, in the method for forming a resist pattern of the present invention, the liquid for liquid immersion lithography is intervened onto the resist film via a resist protective film upon exposure. Examples of such a liquid include water (pure water, deionized water), or a fluorine-based inert liquid. Specific examples of the fluorine-based inert liquid include liquids containing a fluorine-based compound such as C₃HCl₂F₅, C₄F₉OCH₃, C₄F₉OC₂H₅ or C₅H₃F₇ as a main component. Among these liquids, in view of cost, safety, environmental problems and general-purpose properties, the use of water (pure water or deionized water) is preferred. When using the exposure light having a wavelength of 157 nm, the fluorine-based solvent is preferably used in view of less absorption of the exposure light.

The refractive index of the liquid for liquid immersion lithography used is not specifically limited as long as it is within a range “which is larger than the refractive index of an air and smaller than that of the resist composition used”.

After the exposure process in the state of liquid immersion is completed, the substrate is removed from the liquid for liquid immersion lithography, and the liquid is removed from the substrate.

Next, the resist film is subjected to PEB (post exposure bake) without removing the protective film on the exposed resist film, and then developed using an alkaline developing solution composed of an aqueous alkaline solution. The developing solution used in this developer treatment is alkaline, and therefore, the protective film is first dissolved and discharged; and then the soluble portion of the resist film is dissolved and discharged. The developer treatment may be followed by postbaking. Preferably, rinsing is conducted using pure water. In the water rinsing process, water is dripped or sprayed over the surface of the substrate while rotating, thereby washing away the resist protective film component and the resist composition dissolved by the developing solution, and the developing solution on the substrate. Then, a resist pattern, in which a resist film is patterned into a shape corresponding to a mask pattern, is obtained by drying. As described above, in the present invention, removal of the protective film and the development of the resist film are simultaneously achieved by a single developer treatment. Because the protective film formed by the material of the present invention has an improved water-shedding property after exposure is completed, the liquid for liquid immersion lithography can be easily separated, whereby the amount of the liquid for liquid immersion lithography adhered on the protective film decreases, and so-called leakage of the liquid for liquid immersion lithography is prevented.

By forming the resist patterns in this way, resist patterns having fine line widths, particularly line-and-space patterns having a small pitch can be produced with good resolution. Here, the term “pitch” in line-and-space patterns refers to a total distance of a resist pattern width and a space width in the line width direction of the pattern.

### EXAMPLES

Hereinafter, Examples of the present invention will be described to provide a more detailed explanation of the present invention. However, the present invention is not limited to the following Examples.

### Preparation of Resist Composition

The following resin component, acid generator, and nitrogen-containing organic compound were uniformly dissolved in an organic solvent to prepare a resist composition.

As the resin component, 100 parts by mass of a copolymer having a constitutional unit represented by the following chemical formula (21) was used. The ratio of constitutional units a, b, and c for preparing the resin component was that a is 20% by mole, b is 40% by mole, and c is 40% by mole.

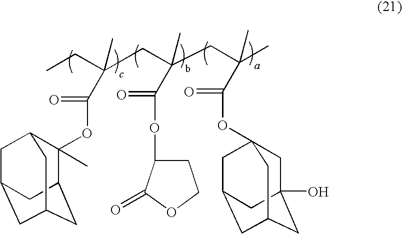

As the acid generator, 2.0 parts by mass of triphenylsulfonium nonafluorobutanesulfonate and 0.8 parts by mass of tri (tert-butylphenyl)sulfonium trifluoromethanesulfonate were used.

In addition, a 7.0% aqueous solution of a mixed solvent of propyleneglycol monomethylether and propyleneglycol monomethylether acetate (mixture ratio=6:4) was used as the organic solvent. As the nitrogen-containing organic compound, 0.25 parts by mass of triethanolamine was used. As the additive, 25 parts by mass of γ-butyrolactone was further added.

### Formation of Resist Film

Using the resist composition prepared as described above, a resist film was formed. Initially, an organic antireflection film composition ARC29 (trade name, by Brewer Co.) was coated onto a silicon wafer using a spinner, followed by heating at 205° C. on a hot plate for 60 seconds for drying, thereby forming an organic antireflection film having a film thickness of 77 nm. Subsequently, the resist composition was coated on this antireflective film using a spinner and dried by prebaking on a hot plate at 130° C. for 90 seconds to form a resist film having a thickness of 225 nm on the antireflective film.

### Example 1

An alkaline-soluble resin represented by the above chemical formula (4) was dissolved in C₄F₉CH₂CH₂OH, whereby a material for forming a protective film, the solid component mass concentration of which was 2.0%, was obtained.

In preparation of the abovementioned material for forming a protective film, the solubility of the alkaline-soluble resin in the abovementioned fluorine atom containing alcohol was visually confirmed. As a result, the above-mentioned alkaline-soluble resin was completely dissolved as shown in Table 1 below.

Then, the obtained material for forming a resist protective film was coated onto the abovementioned film under coating conditions of 1200 rpm using a spin coater. At this time, the coatability of the material for forming a resist protective film was studied. As a result, the coatability was excellent as shown in Table 1 below.

After the abovementioned material for forming a resist protective film was coated, it was heated at 90° C. for 60 seconds, whereby the resist protective film was formed having a film thickness shown in Table 1 below. The obtained resist protective film was rinsed with water for 120 seconds, and then water resistance was studied by measuring the film thickness before and after the rinse. As a result, the film thickness was not substantially altered as shown in Table 1 below, so that the water resistance was confirmed.

Next, the dissolution rate (film thickness conversion: nm/second) of the abovementioned protective film was measured when it was immersed in an alkaline developing solution (TMAH at a concentration of 2.38%) at 23.5° C. As a result, the solubility in the developing solution exceeding 3 nm/second was exhibited.

TABLE 1

| | C₄F₉CH₂CH₂OH | | | | |
|---|---|---|---|---|---|
| | | | | FT* | |
| | | | FT* | after | FT* after |
| | | Coating | after | 120s | Developer |
| | Solubility | properties | coating | DIWRinse | treatment |
| Example 1 | Completely | Excellent | 88.9 nm | 89.1 nm | 0 |
| | dissolved | | | | |
| Example 2 | Completely | Excellent | 97.1 nm | 96.2 nm | 0 |
| | dissolved | | | | |
| Example 3 | Completely | Excellent | 103.0 nm | 101.2 nm | 0 |
| | dissolved | | | | |

*FT represents “Film Thickness”.

### Example 2

An alkaline-soluble resin represented by the chemical formula (5) was dissolved in C₄F₉CH₂CH₂OH, whereby a material for forming a protective film, the solid component mass concentration of which was 2.0%, was obtained.

In preparation of the abovementioned material for forming a protective film, the solubility of the alkaline-soluble resin in the abovementioned fluorine containing alcohol was visually confirmed. As a result, the abovementioned alkaline-soluble resin was completely dissolved as shown in Table 1 above.

Furthermore, the obtained material for forming a resist protective film was coated onto the resist film under coating conditions of 1200 rpm using a spin coater. At this time, the coatability of the material for forming a resist protective film was studied. As a result, the coatability was excellent as shown in Table 1 above.

After the abovementioned material for forming a resist protective film was coated, it was heated at 90° C. for 60 seconds, whereby the resist protective film was formed having a film thickness shown in Table 1 above. The obtained resist protective film was rinsed with water for 120 seconds, and then water resistance was studied by measuring the film thickness before and after the rinse. As a result, the film thickness was not substantially altered as shown in Table 1 above, so that the water resistance was confirmed.

Next, the dissolution rate (film thickness conversion: nm/second) of the abovementioned resist protective film was measured when it was immersed in an alkaline developing solution (TMAH at a concentration of 2.38%) at 23.5° C. As a result, the solubility in the developing solution exceeding 3 nm/second was exhibited.

### Example 3

An alkaline-soluble resin represented by the chemical formula (11), wherein the ratio of la, lb, and m is represented by k=30% by mole, la=20% by mole, lb=10% by mole, m=40% by mole, was dissolved in C₄F₉CH₂CH₂OH whereby a material for forming a protective film, the solid component mass concentration of which was 2.0%, was obtained.

In preparation of the abovementioned material for forming a protective film, the solubility of the alkaline-soluble resin in the abovementioned fluorine containing alcohol was visually confirmed. As a result, the abovementioned alkaline-soluble resin was completely dissolved as shown in Table 1 above.

Furthermore, the obtained material for forming a resist protective film was coated onto the resist film under coating conditions of 1200 rpm using a spin coater. At this time, the coatability of the material for forming a resist protective film was studied. As a result, the coatability was excellent as shown in Table 1 above.

After the abovementioned material for forming a resist protective film was coated, it was heated at 90° C. for 60 seconds, whereby the resist protective film was formed having a film thickness shown in Table 1 above. The obtained resist protective film was rinsed with water for 120 seconds, and then water resistance was studied by measuring the film thickness before and after the rinse. As a result, the film thickness was not substantially altered as shown in Table 1 above, so that the water resistance was confirmed.

Next, the dissolution rate (film thickness conversion: nm/second) of the abovementioned resist protective film was measured when it was immersed in an alkaline developing solution (TMAH at a concentration of 2.38%) at 23.5° C. As a result, the solubility in the developing solution exceeding 3 nm/second was exhibited.

### Examples 4 to 6

The test was conducted in a similar way as described above except that C₃F₇CH₂OH was used in place of C₄F₉CH₂CH₂OH as the fluorine atom containing alcohol. As the alkali-soluble resin, a similar resin to Example 1 was used in Example 4, a similar resin to Example 2 was used in Example 5, and a similar resin to Example 3 was used in Example 6.

As a result, the solubility, coatability, and water resistance of any alkali-soluble resins in Examples 4 to 6 were excellent. In addition, all exhibited the solubility in the developing solution exceeding 3 nm/second.

### Examples 7 to 9

The materials for forming a protective film used in Examples 1 to 3 were coated on the resist film, followed by heating at 90° C. for 60 seconds to form a protective film having a film thickness of 70 nm. In Example 7, the protective film was obtained from the material for forming a protective film used in Example 1; in Example 8, the protective film was obtained from the material for forming a protective film used in Example 2; and in Example 9, the protective film was obtained from the material for forming a protective film used in Example 3.

Next, a pattern light was irradiated (exposed) through a mask pattern using an ArF excimer laser (wavelength: 193 nm) with an exposure apparatus (Nikon-S302A, manufactured by Nikon Co.). Then, as the liquid immersion lithography process, pure water was dripped continuously onto the resist protective film at 23° C. for 2 minutes while rotating the silicon wafer on which the resist film and the resist protective film had been disposed after exposure. The process of this part is an exposure process in a completely immersed state in an actual production process. However, the constitution is simplified such that the resist film is exposed beforehand, and then pure water as a liquid for liquid immersion lithography is loaded on the resist film and the resist protective film after the exposure, whereby only an influence of the liquid for liquid immersion lithography on the resist film and the resist protective film can be evaluated.

After the process of dropping pure water, a PEB treatment was conducted at 115° C. for 90 seconds. Then, without removing the protective film, the film was developed using an alkaline developing solution at 23° C. for 60 seconds. The alkaline developer was an aqueous solution of 2.38% by mass tetramethylammonium hydroxide. The developing step could remove the protective films of Examples 7 to 9 completely, and the resist film could be developed properly.

Thus resulting 300 nm resist pattern of 1:2 line-and-space was observed under a scanning electron microscope (SEM), which revealed that the pattern profile had a proper rectangular shape and was almost equal to the resist pattern obtained by a dry process.

### INDUSTRIAL APPLICABILITY

As described above, according to the present invention, even if a resist film is formed using any common resist composition, it is possible to obtain a highly accurate resist pattern which is free from surface roughness, such as a resist pattern with a T-top shape, having high sensitivity and excellent resist pattern profile, and also being excellent in depth of focus and exposure latitude, regardless of the type of liquid for liquid immersion lithography used, particularly even in the case in which water or a fluorine-based medium is used in the liquid immersion lithography process. In addition, the film is dense and permeation of an environmental amine component can be remarkably blocked, and also resistance to post exposure delay of the resist film can be enhanced. Consequently, when using a protective film of the present invention, a resist pattern can be effectively formed using a liquid immersion lithography process.

1. A material for forming a protective film of a resist film top layer comprising: a water-soluble or alkali-soluble polymer component; and a fluorine atom containing alcohol.

2. The material according to claim 1, wherein the resist film is subjected to a liquid immersion lithography process.

3. The material according to claim 1, wherein the fluorine atom containing alcohol has the number of the fluorine atoms larger than that of the hydrogen atoms included in the molecule thereof.

4. The material according to claim 1, wherein the fluorine atom containing alcohol has 4 to 12 carbon atoms.

5. The material according to claim 1, the fluorine atom containing alcohol is an alcohol represented by the following chemical formula (1):
C₄F₉CH₂CH₂OH (1), and/or
an alcohol represented by the following chemical formula (2):
C₃F₇CH₂OH (2).

6. The material according to claim 1 further comprising a crosslinking agent.

7. The material according to claim 1 further comprising an acidic component.

8. The material according to claim 7, wherein the acidic component is a fluorocarbon compound.

9. The material according to claim 2, wherein the resist film is exposed to a light in the liquid immersion lithography process through a liquid for liquid immersion lithography having a predetermined thickness and a refractive index higher than that of air and lower than that of the resist film, which is intervened in a pathway allowing the exposure light for lithography to reach the resist film.

10. A method for forming a resist pattern using a liquid immersion lithography process comprising the steps of:
forming a resist film on a substrate;
forming a protective film on the resist film using the material for forming a protective film according to claim 1;
placing the liquid for liquid immersion lithography at least on the protective film of the substrate laminated with the resist film and the protective film;
selectively irradiating light to the resist film through the liquid for liquid immersion lithography and the protective film; performing a heat treatment if necessary; and
subjecting the protective film and the resist film to a developer treatment using an alkaline developer solution so as to simultaneously remove the protective film and obtain the resist pattern.
